(19) United States
(12) Patent Application Publication
(10) Pub. No.: US 2025/0331403 A1
(43) Pub. Date: Oct. 23, 2025

(54) DISPLAY PANEL AND DISPLAY APPARATUS

(71) Applicant: Hubei Yangtze Industrial Innovation Center Of Advanced Display Co., Ltd., Wuhan (CN)

(72) Inventors: Jiachang GU, Wuhan (CN); Chujie YU, Wuhan (CN); Kang KANG, Wuhan (CN); Wenjing CHEN, Wuhan (CN)

(73) Assignee: Hubei Yangtze Industrial Innovation Center Of Advanced Display Co., Ltd., Wuhan (CN)

(21) Appl. No.: 18/746,033

(22) Filed: Jun. 18, 2024

(30) Foreign Application Priority Data
Apr. 17, 2024 (CN) 202410465146.7

(51) Int. Cl. H10K 59/80; H10K 59/35

(52) U.S. Cl. CPC H10K 59/879; H10K 59/353

(57) ABSTRACT

The present application discloses a display panel and a display apparatus. The display panel includes a first area and a second area, a light transmittance of the second area is greater than that of the first area, wherein the display panel includes a substrate, a light-emitting layer and a light processing layer. The light-emitting layer is arranged on the substrate and includes a plurality of light-emitting units arranged at intervals; the light processing layer is arranged on a side of the light-emitting layer away from the substrate and includes a first refraction layer and a second refraction layer that covers the first refraction layer, wherein the first refraction layer is provided with a light outlet overlapped with the light-emitting unit in a thickness direction of the substrate, and the refractive index of the second refraction layer is greater than that of the first refraction layer.

### CROSS-REFERENCE TO RELATED APPLICATION

This application is based on and claims priority to Chinese Patent Application No. 202410465146.7, filed on Apr. 17, 2024 and titled “display panel and display apparatus”, the contents of which is incorporated herein by reference in their entirety.

### TECHNICAL FIELD

The present application relates to the technical field of display, and in particular, to a display panel and a display apparatus.

### BACKGROUND

A Camera Under Panel technology, also known as CUP technology, is to hide a front camera under a screen without affecting the display effect of the whole screen. With a special pixel design and transparent electrode introduction, the screen transmittance of a CUP area can be improved, which enables the external light to get into the sensor inside the camera directly by passing through the CUP area, so as to improve the imaging quality.

In order to improve the light input of the CUP area, it is usually necessary to reduce the sub-pixel area in the area, so as to increase light input by increasing the distance between the adjacent sub-pixels. Since the reduction of the sub-pixel area will lead to the decrease of the brightness of the area, a Micro Lens Panel (MLP) technology, which is generally called micro-lens technology, is usually used for the sub-pixel, so as to increase the light input of the CUP area on the basis of ensuring the entering of light.

However, although the technology of setting MLP micro-lens on the sub-pixel can improve the display brightness of the CUP area, the structure of the MLP micro-lens itself will affect the light input of the area, since the light will be blocked by the structure, the light input will be reduced, and finally the imaging quality will be affected.

### SUMMARY

Embodiments of the present application provide a display panel and a display apparatus, aiming at increasing the input of external light on the basis of improving the brightness of the display panel, and finally improving the imaging effect.

Embodiments in an aspect of the present application provide a display panel, including a first area and a second area, a light transmittance of the second area is greater than that of the first area, the display panel includes a substrate; a light-emitting layer and a light processing layer, wherein the light-emitting layer is arranged on the substrate and includes a plurality of light-emitting units arranged at intervals; the light processing layer is arranged on a side of the light-emitting layer away from the substrate and includes a first refraction layer and a second refraction layer that covers the first refraction layer, the first refraction layer is provided with a light outlet which is overlapped with the light-emitting unit in a thickness direction of the substrate, and a refractive index of the second refraction layer is greater than that of the first refraction layer; wherein in the thickness direction, a ratio of an area of an orthographic projection of the first refraction layer to that of the second refraction layer on the second area is less than a ratio of an area of the orthographic projection of the first refraction layer to that of the second refraction layer on the first area.

Embodiments in another aspect of the present application provide a display apparatus including the display panel as described above.

### BRIEF DESCRIPTION OF THE DRAWINGS

Features, advantages and technical effects of exemplary embodiments of the present application will be described with reference to the accompanying drawings.

FIG. 1 is a structural schematic diagram of a display panel in the prior art.

FIG. 2 is a plan view of a display panel in the prior art.

FIG. 3 is a structural schematic diagram of a display panel according to an embodiment of the present application.

FIG. 4 is a plan view of the display panel according to an embodiment of the present application.

FIG. 5 is a structural schematic diagram of another display panel according to an embodiment of the present application.

FIG. 6 is a plan view of another display panel according to an embodiment of the present application.

FIG. 7 is a structural schematic diagram of yet another display panel according to an embodiment of the present invention.

FIG. 8 is a plan view of yet another display panel according to an embodiment of the present application.

FIG. 9 is a partial plan view of a display panel according to an embodiment of the present application.

FIG. 10 is a plan view of yet another display panel according to an embodiment of the present application.

FIG. 11 is a structural schematic diagram of yet another display panel according to an embodiment of the present application.

FIG. 12 is a structural schematic diagram of yet another display panel according to an embodiment of the present application.

### DESCRIPTION OF REFERENCE SIGNS

100—display panel; AA—first area; NA—second area; M—first part; N—second part.
10—substrate; 20—light-emitting layer; 21—light-emitting unit; 1—first sub-pixel; 2—second sub-pixel; 3—third sub-pixel; 22—pixel limiting portion.
30—light processing layer; 31—first refraction layer; 32—second refraction layer; 33—light outlet; 34—light inlet; 35—first refraction portion; 36—light contact surface;
40—encapsulation layer; 50—touch layer.

In the drawings, the same reference signs indicate the same elements. The accompanying drawings are not drawn to the actual scale.

### DETAILED DESCRIPTION

Features and exemplary embodiments of various aspects of the present application will be described in detail below. In the following detailed description, many specific details are provided in order to provide a comprehensive understanding of the present application. However, it is obvious to those skilled in the art that the present application may be implemented without some of these specific details. The following description of embodiments is only intended to provide a better understanding of the present application by showing examples of the present application. In the drawings and the description below, at least some of the known structures and techniques are not shown in order to avoid unnecessary ambiguity to the present application, and for clarity, the size of part of the structure may be exaggerated. In addition, features, structures or characteristics described below may be combined in one or more embodiments in any appropriate manner.

The orientation terms appearing in the following description are the directions shown in the drawings and do not define the specific structure of the display panel and the display apparatus of the present application. In the description of the present application, it should also be noted that, unless otherwise clearly defined and limited, the terms “install” and “connect” should be understood in a broad sense, for example, it can be a fixed connection, a detachable connection, or an integral connection; it can be a direct or indirect connection. For ordinary skills in the art, the specific meaning of the above terms in the present application can be understood according to the specific circumstances.

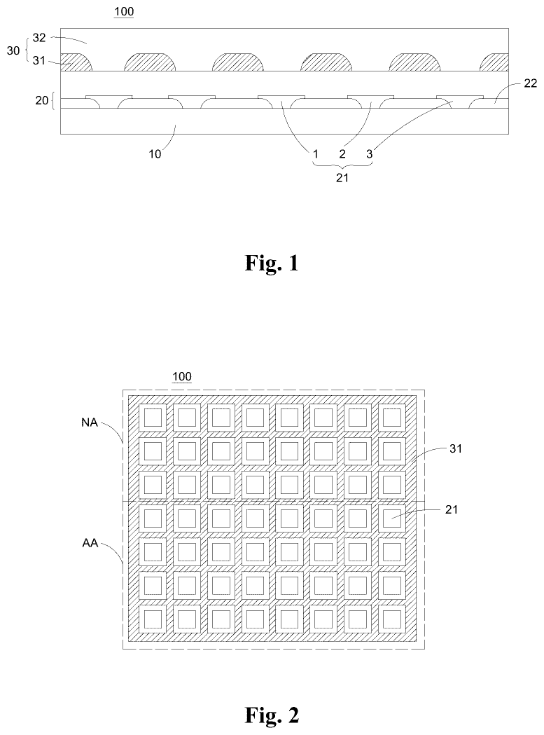

In order to better understand the present application, a display panel and a display apparatus according to embodiments of the present application are described in detail below in conjunction with FIGS. 1-12.

Referring to FIGS. 1-8, a display panel 100 is provided according to embodiments of the present application, the display panel 100 includes a first area AA and a second area NA, wherein a light transmittance of the second area NA is greater than that of the first area AA. The display panel 100 includes a substrate 10; a light-emitting layer 20 and a light processing layer 30, wherein the light-emitting layer 20 is arranged on the substrate 10 and includes a plurality of light-emitting units 21 arranged at intervals; the light processing layer 30 is arranged on a side of the light-emitting layer 20 away from the substrate 10 and includes a first refraction layer 31 and a second refraction layer 32 that covers the first refraction layer 31, the first refraction layer 31 is provided with a light outlet 33 which is overlapped with the light-emitting unit 21 in a thickness direction of the substrate 10, and a refractive index of the second refraction layer 32 is greater than that of the first refraction layer 31; wherein in the thickness direction, a ratio of an area of an orthographic projection of the first refraction layer 31 to that of the second refraction layer 32 on the second area NA is less than a ratio of an area of the orthographic projection of the first refraction layer 31 to that of the second refraction layer 32 on the first area AA.

In the embodiment, as shown in FIGS. 1 and 2, the light transmittance of the second area NA of the display panel 100 is greater than that of the first area AA. Optionally, the first area AA may be a conventional display area for forming a conventional display, and the second area NA may be a camera under panel area, which can also have normal display on the basis of having an imaging function, so that the display panel 100 can forms a complete picture.

Considering that the light transmittance of the second area NA is larger than that of the first area AA, the light-emitting unit 21 in the second area NA often has a smaller luminous area, which can improve the light transmittance between adjacent light-emitting units 21, which, however, will reduce the luminous quantity of the second area NA and darken the brightness of the second area NA relative to the first area AA, thus resulting in non-uniformity of luminance of the same display panel.

Therefore, in this embodiment, a light processing layer 30 is arranged on the light-emitting layer 20. Optionally, the light processing layer 30 may be a micro-lens (MLP) structure, wherein the first refraction layer 31 is arranged around the light-emitting unit 21, the second refraction layer 32 covers the first refraction layer 31, the refractive index of the second refraction layer 32 is greater than that of the first refraction layer 31, the first refraction layer 31 may be a low refraction layer (LRL) and the second refraction layer 32 may be a high refraction layer (HRL), and the display brightness may be increased by using the cooperative relationship between the first refraction layer 31 and the second refraction layer 32.

Specifically, a plurality of light outlets 33 are arranged on the first refraction layer 31, and each of the plurality of light outlets 33 corresponds to a corresponding light-emitting unit 21. When the light-emitting unit 21 is lighted up, after the emitted light is processed by the total reflection of the first refraction layer 31 and the second refraction layer 32, the reflected light is converged from a large viewing angle to an orthographic viewing angle for output, thereby improving the display brightness of the light emitting unit 21 at the orthographic viewing angle.

According to the above analysis, since the display brightness of the second area NA is lower than that of the first area AA, it is often necessary to set the light processing layer 30 at the second area NA, so that the display brightness of the second area NA can be increased on the basis that the second area NA having a higher light transmittance, which ensures the uniformity of the display brightness of the display panel 100. At the same time, in order to join the display brightness of the first area AA and the second are NA, the light processing layer 30 may also be arranged on the light-emitting units 21 of the first area AA to appropriately improve the display brightness at the first area AA.

In the present application, it is mainly considered that although the use of the light processing layer 30 can appropriately improve the display brightness of the second area NA, however, the light processing layer 30 will block the incoming light from the outside to a certain extent at the same time, which can easily decrease the light transmittance of the second area NA and adversely affect the imaging in the later stage. Therefore, in the embodiment, the structure of the light processing layer 30 in the first area AA and the second area NA is designed differently.

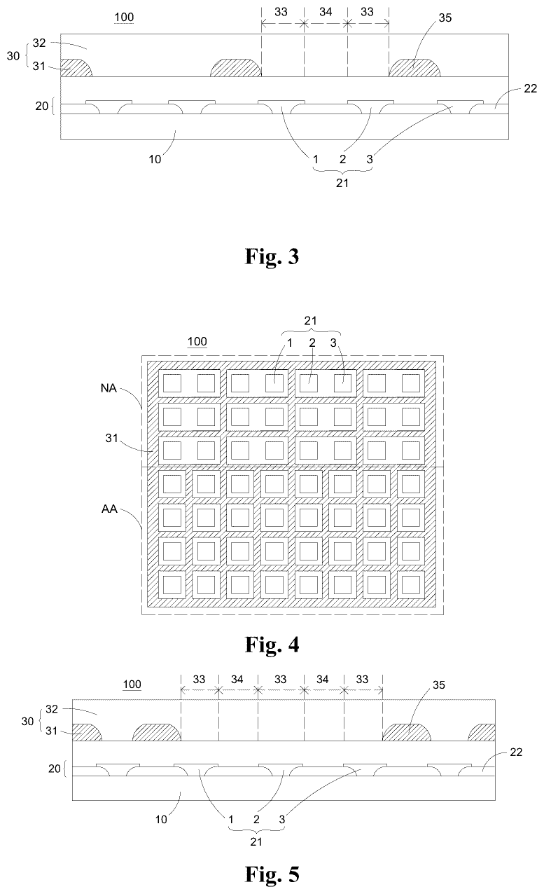

Since in the light processing layer 30, the first refraction layer 31 forms a greater blocking effect on the external light input, it is necessary to adjust the proportion of the first refraction layer 31 to the second refraction layer 32, that is, on the basis of using the light processing layer 30 to improve the display brightness at the second area NA, the coverage of the first refraction layer 31 can be appropriately reduced, as shown in FIGS. 3 to 8. In this way, the optical coordination relationship between the first refraction layer 31 and the second refraction layer 32 can not only increase the display brightness at the orthographic viewing angle, but also reduce the influence of the first refraction layer 31 on the incoming light, thereby improving the light transmittance of the second area NA and ensuring the imaging effect.

The embodiment of the present application provides a display panel 100, wherein a light processing layer 30 is arranged on the light-emitting layer 20, a first refraction layer 31 and a second refraction layer 32 with different refractive indexes are arranged in the light processing layer 30, and a light outlet 33 corresponding to a corresponding light-emitting unit 21 is arranged on the first refraction layer 31. Total internal reflection of the light is formed by coordination of the refractive index difference between the first refraction layer 31 and the second refraction layer 32. Specifically, when the light-emitting unit 21 emits light, one part of the light is emitted through the light outlet 33 at the orthographic viewing angle, and the other part of the light at the large viewing angle is emitted to a contact surface between the first refraction layer 31 and the second refraction layer 32 by passing through the light outlet 33. The change of refractive indexes causes a total reflection of the light to be formed at this position, leading to the light at the large viewing angle is reflected to the orthographic viewing angle for light output, so that more light is emitted from the orthographic viewing angle of the light outlet 33, the display brightness of the first area AA and the second area NA of the display panel 100 can be thus improved. On this basis, the area ratio of the first refraction layer 31 to the second refraction layer 32 in the first area AA and the second area NA can be adjusted, and by making the area proportion of the first refraction layer 31 in the second area NA smaller than that in the first area AA, the influence of the light processing layer 30 on the light input in the second area NA is reduced, so that the light input in the second area NA is larger than that in the first area AA. Therefore on the basis of improving the display brightness of the second area NA by using the light processing layer 30, the light input in the second area NA can also be increased, and finally the imaging effect can be improved and the influence of the light processing layer 30 on the imaging can be reduced.

As an optional embodiment, referring to FIG. 3, the light-emitting layer 20 includes a plurality of pixel limiting portion 22 which encloses a plurality of pixel openings, and the light-emitting unit 21 is arranged in each of the pixel openings. In the second area NA, the first refraction layer 31 is provided with a light inlet 34, a part of the second refraction layer 32 is filled in the light inlet 34 and the light outlet 33, and an orthographic projection of the light inlet 34 in the thickness direction is located on the pixel limiting portion 22, and the light outlet 33 is arranged corresponding to a corresponding pixel opening in the thickness direction.

In order to improve the light transmittance of the second area NA of the display panel 100, the light inlet 34 may be arranged on the first refraction layer 31 at the second area NA, wherein the light inlet 34 is arranged corresponding to a corresponding pixel limiting portion 22 at the bottom, and the pixel limiting portions 22 enclose the pixel openings, and the light-emitting unit 21 is arranged in a corresponding pixel opening.

Optionally, the pixel limiting portions 22 may be formed by a vapor deposition process and etched to form a plurality of pixel openings corresponding to a plurality of light-emitting units 21. Since the pixel limiting portion 22 is usually made of an organic transparent material, the light inlet 34 arranged on the first refraction layer 31 of the second area NA corresponds to the corresponding pixel limiting portion 22, so that after the external light passes through the light inlet 34, the light is transmitted at the pixel limiting portion 22, which improves the light transmittance at the second area NA.

At the same time, the light outlet 33 arranged on the first refraction layer 31 corresponds to the corresponding pixel opening enclosed by the pixel limiting portions 22 at bottom, the light emitted by the light-emitting unit 21 in the pixel opening passes through the light outlet 33, and under the cooperative action of the first refraction layer 31 and the second refraction layer 32, the luminance at the light outlet 33 is improved, and the display brightness of the second area NA is ensured.

It can be understood that the light inlets 34 and the light outlets 33 on the first refraction layer 31 are arranged alternately, and the second refraction layer 32 is simultaneously filled in the light inlets 34 and the light outlets 33, the display brightness is increased at the light outlets 33 and the light transmittance is increased at the light inlets 34, the light output and light input requirements at the second area NA are met at the same time, therefore, the imaging effect of the second area NA is guaranteed on the basis of normal display.

The embodiment of the present application provides a display panel 100, by arranging the light inlet 34 on the first refraction layer 31 to correspond to the pixel limiting portion 22, and arranging the light outlet 33 to correspond to the light-emitting unit 21 in the pixel opening, the second area NA can not only have an improved display brightness, but also have an increased light transmittance. On the basis of the display brightness connection with the first area AA being met, the imaging process of the second area NA can be improved and the overall functionality of the display panel 100 can be improved.

As an optional embodiment, refer to FIG. 3, the first refraction layer 31 includes a plurality of first refraction portions 35, in the second area NA, an orthographic projection of the first refraction portion 35 in the thickness direction is located on a corresponding pixel limiting portion 22, and the first refraction portions 35 encloses the light outlets 33 and the light inlets 34, wherein the light outlets 33 and the light inlets 34 are arranged alternately.

For the specific structure of the light outlet 33 and the light inlet 34 in the first refraction layer 31, specifically, the light outlet 33 and the light inlet 34 are enclosed by the first refractive portions 35. Optionally, the first refraction portion 35 may be a micro-lens with a low refractive index, the first refraction portions 35 may be arranged around the light-emitting unit 21 and form the light outlet 33 with a corresponding shape, and the pixel limiting portion 22 between the adjacent light-emitting units 21 corresponds to the light inlet 34.

optionally, the light inlet 34 and the light outlet 33 on the first refraction layer 31 are arranged alternately so that the light inlet 34 and the light outlet 33 can be spaced by the first refraction portion 35, and the light inlet 34 and the light outlet 33 can be continuous with each other to form a complete opening, which is not limited herein.

The embodiment of the present application provides a display panel 100, by alternately setting the light inlet 34 and the light outlet 33 on the first refraction layer 31, light input and output can be achieved on the first refraction layer 31 simultaneously, the light emitted by the light-emitting unit 21 is reflected via the total internal reflection at the contact surface of the first refraction layer 31 and the second refraction layer 32, and then output through the light outlet 33, at the same time, the external ambient light gets into the off-screen photosensitive elements through the light inlet 34, the brightness and transmittance are thus improved simultaneously.

As an optional embodiment, referring to FIGS. 3 to 6, the light-emitting unit 21 includes a plurality of sub-pixels arranged at intervals, the orthographic projection of the first refraction portion 35 in the thickness direction continuously surrounds at least two adjacent sub-pixels, each sub-pixel is arranged corresponding to a corresponding light outlet 33 in the thickness direction, and the pixel limiting portion 22 between the adjacent sub-pixels is arranged corresponding to the corresponding light inlet 34 in the thickness direction. At least part of the light outlets 33 and the light inlets 34 are arranged at intervals.

Optionally, each of light-emitting units 21 includes a plurality of sub-pixels, each of the plurality of sub-pixels can emit red, green or blue monochromatic light, and color mixing may be completed after the light being emitted, wherein each of the light outlets 33 on the first refraction layer 31 is arranged corresponding to a corresponding sub-pixel, the first refraction portion 35 can be arranged around two sub-pixels at the same time, and the pixel limiting portion 22 between the two sub-pixels corresponds to the light inlet 34 on the first refraction layer 31.

For example, the first refraction portion 35 surrounds a red sub-pixel and a green sub-pixel at the same time, and the first refraction portion 35 can be used to improve the display brightness after the mixing of the red and green colors being completed. The first refraction portion 35 between the two sub-pixels can be cancelled, so that the blocking of the incoming light caused by the first refraction portion 35 can be reduced and the light transmittance between the two sub-pixels can be improved.

According to different actual requirements, the first refraction portion 35 can be used to surround three sub-pixels at the same time, wherein the first refraction portion 35 can be cancelled between the adjacent sub-pixels, so that the light transmittance between the two adjacent sub-pixels can be further improved, and the light inlet 34 and the light outlet 33 can be formed to be partially continuous on the first refraction layer 31.

In this embodiment, instead of setting the first refraction portion 35 on each sub-pixel to improve the display brightness, the first refraction portion 35 is selectively arranged around the sub-pixel, that is, the first refraction portion 35 around part of the sub-pixels can be cancelled, so that the blocking of the incoming light by the first refraction portion 35 can be reduced and the overall light transmittance can be improved.

In this application, there is no special limitation on the number of sub-pixels surrounded simultaneously by the first refraction portion 35, which needs to be determined according to the resolution of the second area NA. When the resolution of the second area NA is high, it is not necessary to set a plurality of first refraction portions 35 to improve the display brightness, the first refraction portions 35 thus can be cancelled for a large number of sub-pixels, in other words, the first refraction portion 35 can be arranged simultaneously around multiple sub-pixels. In the opposite situation, more first refraction portion 35 need to be used to improve the display brightness, it is necessary to set the first refraction portion 35 around each sub-pixel, and minimize the cancellation of the first refraction portions 35.

Thus, for the second area NA, it is necessary to comprehensively consider the light input and light output of the area to ensure that both of them meet the display requirements at the same time, so as to adjust the structure of the first refraction layer 31 accordingly, specifically, the structure of the first refraction portion 35 may be adjusted to obtain different distributions of the light inlet 34 and the light outlet 33.

The embodiment of the present application provides a display panel 100, by using the first refraction portion 35 to surround at least two sub-pixels, the first refraction portion 35 between the two sub-pixels can be cancelled, thereby improving the light transmittance between the two sub-pixels, improving the luminous brightness of the sub-pixels and reducing the influence of the first refraction portion 35 on the incoming light. On this basis, the different requirements for the light output of the second area NA with different resolutions can also be met, a more flexible resolution adjustment as well as structural diversity and adaptability can be achieved.

As an optional embodiment, referring to FIGS. 3 and 4. The light-emitting unit 21 includes a first sub-pixel 1, a second sub-pixel 2 and a third sub-pixel 3 arranged at intervals. The orthographic projection of the first refraction portion 35 in the thickness direction continuously surrounds the first sub-pixel 1 and the second sub-pixel 2 of the first light-emitting unit, the first sub-pixel 3 of the first light-emitting unit and the first sub-pixel 1 of its adjacent second light-emitting unit, and a second sub-pixel 2 and a third sub-pixel 3 of the second light-emitting unit.

In this embodiment, the first refraction portion 35 is used to surround the two adjacent sub-pixels, and the first refraction portion 35 between any two sub-pixels is cancelled, thereby increasing the amount of light input between the two sub-pixels. At the same time, the luminous brightness of the mixed color of the two sub-pixels can be increased with the surrounding of the first refraction portion 35.

Optionally, each light-emitting unit 21 includes a first sub-pixel 1, a second sub-pixel 2, and a third sub-pixel 3, which may be a red sub-pixel, a green sub-pixel, and a blue sub-pixel, respectively. With the light processing layer 30 arranged on the light-emitting layer 20, in which the first refraction portion 35 is arranged in units of two adjacent sub-pixels and the first refraction portion 35 between two sub-pixels is cancelled, which can increase the light input of the second area NA.

The embodiment of the present application provides a display panel 100, with the optical processing of two sub-pixels using the first refraction portion 35, the light transmittance between two sub-pixels can be improved. The first refraction portion 35 can also be used to converge the light at the orthographic viewing angle, which is more consistent with the use of low resolution at the second area NA. On the basis of the brightness of the display of the second area NA being ensured, the light transmittance of the region can be appropriately improved.

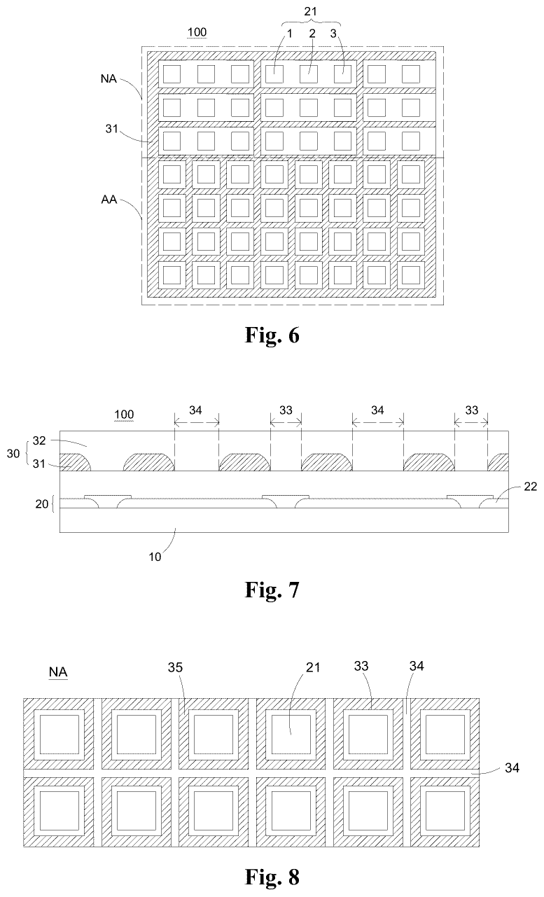

As an optional embodiment, referring to FIGS. 5 and 6, the light-emitting unit 21 includes the first sub-pixel 1, the second sub-pixel 2 and the third sub-pixel 3 arranged at intervals. The orthographic projection of the first refraction portion 35 in the thickness direction surrounds the first sub-pixel 1, the second sub-pixel 2 and the third sub-pixel 3 at the same time.

In the present embodiment, the optical processing is carried out in units of a single light-emitting unit 21, that is, three sub-pixels in the single light-emitting unit 21 are surrounded by the first refractive unit 35, and the brightness of the three sub-pixels is enhanced after color mixing being completed. Therefore, the first refraction portions 35 among the three sub-pixels can be cancelled to improve the light transmittance among the three sub-pixels.

The embodiment of the present application provides a display panel 100, with a single light-emitting unit 21 being surrounded by the first refraction portion 35, the first refraction portion 35 between sub-pixels in the single light-emitting unit 21 can be cancelled, so that on the basis of the first refraction portion 35 being used in the optical processing of the light-emitting unit 21, the light transmittance between the sub-pixels in the light-emitting unit 21 is also improved. Compared with the previous embodiment, the present embodiment cancels the arrangement of more the first refraction portions 35, which reduces the improvement of the display brightness, and is more consistent with the arrangement of the second area NA with a higher resolution, thus the light transmittance of the second area NA can be further improved.

As an optional embodiment, the orthographic projection of the first refraction portion 35 in the thickness direction is arranged around the edge of the second area NA, and the light outlet 33 and the light inlet 34 enclosed by the first refraction portions 35 are all continuous with each other.

In the present embodiment, the arranged first refraction portion 35 is further reduced, that is, the first refraction portions 35 is arranged only around the edge of the second area NA, thereby canceling the first refraction portion 35 between sub-pixels in the second area NA, so that an input outlet 34 can be formed between any two sub-pixels and is continuous with the light outlet 33 corresponding to a corresponding sub-pixel.

In this way, the first refraction portion 35 arranged around the second area NA can process the overall light output of the second area NA, thereby improving the display brightness of the second area NA. When the rest of the first refraction portions 35 in the second area NA are cancelled, the light transmittance in the second area NA can be fully increased, and the blocking of the incoming light by the first refraction portion 35 can be greatly reduced.

The embodiment of the present application provides a display panel 100, wherein the first refraction portion 35 is used to surround the edge of the second area NA, on the basis of improving the display brightness of the second area NA, the first refraction portion 35 in the second area NA is fully cancelled, which is suitable for the structure of the second area NA with a higher resolution, that is, in the structure there is little need to increase the brightness, the light transmittance of the second area NA can be maximized and a better imaging effect can be achieved.

As an optional embodiment, referring to FIGS. 7 and 8, the light-emitting unit 21 includes a plurality of sub-pixels arranged at intervals, and the orthographic projection of the first refraction portion 35 in the thickness direction surround a corresponding sub-pixel. The sub-pixel is arranged corresponding to the light outlet 33 in the thickness direction, and the first refraction portions 35 corresponding to the adjacent sub-pixels are arranged at an interval to form the light inlet 34, wherein the light outlet 33 and the light inlet 34 are spaced from each other.

When the display resolution of the second area NA is low, the first refraction portion 35 needs to be arranged at the corresponding position of each sub-pixel, thereby improving the brightness of each sub-pixel, and the light outlet 33 enclosed by the first refraction portions 35 is arranged corresponding to each sub-pixel.

Since the light transmittance of the second area NA still needs to be improved, the light inlet 34 is arranged between the first refraction portions 35 corresponding to the adjacent sub-pixels, that is, the first refraction portion 35 of the two adjacent sub-pixels are spaced apart so that the first refraction layer 31 is hollowed out to obtain the light inlet 34.

Under the action of the spaced first refraction portions 35, the light inlet 34 and the light outlet 33 are arranged alternately, and on the basis of ensuring that each sub-pixel has an enhanced luminous brightness, the incoming light can be formed between adjacent sub-pixels, which fully improves the light transmittance of the second area NA.

The embodiment of the present application provides a display panel 100, wherein the light efficiency can be improved by setting a first refraction portion 35 for each sub-pixel, and with the light inlet 34 being arranged between the adjacent first refraction portions 35, not only the display requirements of the second area NA with a low resolution can be met, but the light transmittance requirements of the second area NA can also be met, the influence of the first refraction portion 35 on the incoming light can be reduced as much as possible, and a better imaging effect can be achieved.

As an optional embodiment, the orthographic projection of the light outlet 33 in the thickness direction at least covers a corresponding sub-pixel.

The light outlet 33 arranged on the first refraction layer 31 needs to be arranged corresponding to the sub-pixel at the bottom. Optionally, the shape of the light outlet 33 can match the shape of the sub-pixel, and the size of the light outlet 33 can be appropriately larger than the size of the sub-pixel, which is beneficial to the output of light to improve the display brightness.

In the present application, there is no special restriction on the specific shape and size of the light outlet 33, as long as the shape and size of the light outlet 33 matching the corresponding sub-pixel. The light passing through the light outlet 33 converges toward the orthographic viewing angle, thereby improving the display brightness of the sub-pixel.

The embodiment of the present application provides a display panel 100, by configuring the light outlet 33 corresponding to the sub-pixel and making the light outlet 33 at least covering the sub-pixel, it's beneficial to the light export of the sub-pixel for improving the display brightness.

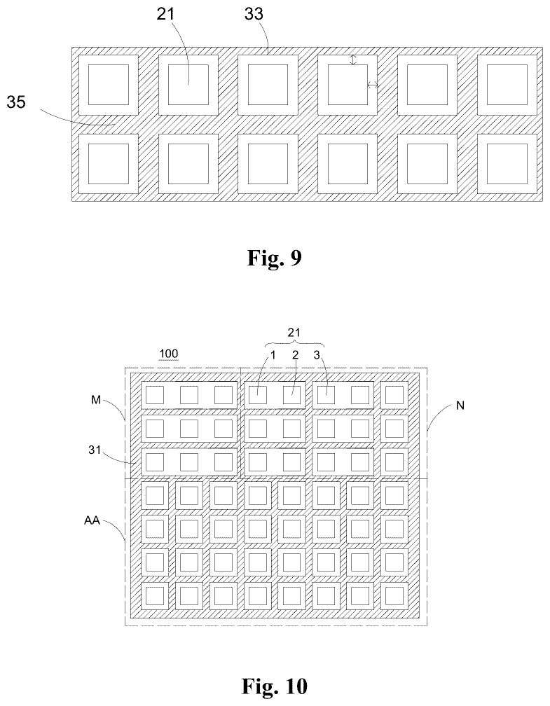

As an optional embodiment, referring to FIG. 9, a size of the orthographic projection of the light outlet 33 in the thickness direction is larger than a size of the pixel opening and the distance between the two is 0-2 μm.

The embodiment of the present application provides a display panel 100, wherein a distance of 0-2 μm is formed between the arranged light outlet 33 and the sub-pixel. After experimental verification, the light outlet 33 has a better light efficiency with the numerical range, which is beneficial to the occurrence of total reflection under the action of the first refraction portion 35.

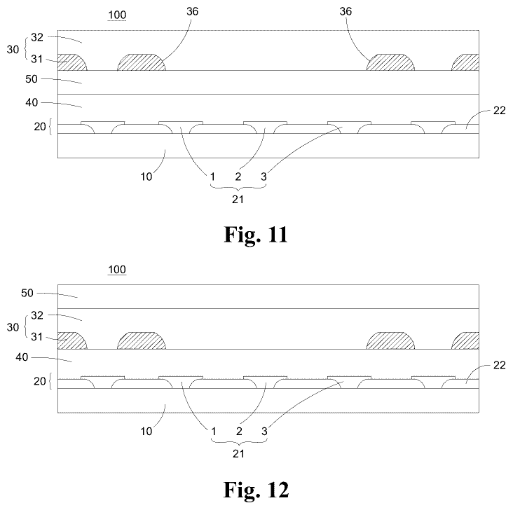

As an optional embodiment, referring to FIG. 10, the light-emitting unit 21 includes a plurality of sub-pixels arranged at intervals, the second area NA includes a first part M and a second part N, the resolution of the first part M is greater than the resolution of the second part N, and the orthographic projection of the first refraction portion 35 in the first part M in the thickness direction is arranged around at least two adjacent sub-pixels at the same time, and the orthographic projection of the first refraction portion 35 in the second part N in the thickness direction surrounds a corresponding sub-pixel.

The second area NA in the present embodiment has display differentiation, that is, the resolution of the first part M is greater than that of the second part N, so that the first refraction portion 35 needs to be differentiated for different parts of the second area NA.

It can be seen from the above analysis that when the resolution of the second area NA is low, it is necessary to increase the number of the first refraction portions 35 to improve the display brightness, that is, to set the first refraction portion 35 for each sub-pixel, and an inlet 34 needs to be formed between the adjacent first refraction portions 35 at the same time to synchronously ensure the light transmittance of the second part N.

For the first part M with a higher resolution, the setting of the first refraction portions 35 can be reduced at this time, and the first refraction portion 35 may be arranged around a plurality of sub-pixels at the same time, so that the first refraction portion 35 between the adjacent sub-pixels can be appropriately cancelled, which can fully reduce the influence of the first refraction portion 35 on the incoming light, and finally, on the basis that the first part M itself has a higher display brightness, the light transmittance of the first part M is also improved.

The embodiment of the present application provides a display panel 100, wherein there is resolution difference existed between different parts of the second area NA, through the different arrangements of the first refraction portion 35, different light processing can be carried out on different parts of the second area NA, so that the light transmittance of the different parts of the second area NA can be improved while the display brightness is met.

As an optional embodiment, referring to FIG. 10, in a direction from the first part M to the second part N, the number of sub-pixels surrounded by the first refraction portion 35 shows a decreasing trend.

Considering the display connection between the first part M and the second part N in the second area NA, since the first refraction portion 35 in the first part M surrounds a larger number of sub-pixels, the number of sub-pixels processed by the first refraction portion 35 in the first part M can be gradually reduced as gradually approaching the second part N, and finally the first refraction portion 35 is arranged around a corresponding sub-pixel to gradually meet the resolution requirements of the second part N.

The embodiment of the present application provides a display panel 100, wherein the number of sub-pixels surrounded by the first refraction portion 35 is designed to be gradually changed, the first part M and the second part N with different resolutions in the second area NA have a better display connection effect, avoiding the sudden change of display brightness and ensuring the overall light transmittance of the second area NA.

As an optional embodiment, referring to FIG. 11, the first refraction portion 35 includes an optical contact surface 36, which is located on a side of the first refraction portion 35 close to the light inlet 34, and the optical contact surface 36 is arranged as an inclined plane.

Optionally, the light of the sub-pixel can pass through the light outlet 33, and in order to make the light having a better export effect, the light contact surface 36 which is directly cooperated with the light can be set as an inclined plane, thus a better light efficiency can be achieved. In the present application, there is no special limitation on the inclined plane angle of the light contact surface 36, and the value can be determined according to specific experiments, and an appropriate angle range can be selected to meet the demand of light export.

The embodiment of the present application provides a display panel 100, wherein the light contact surface 36 of the first refraction portion 35 is arranged as an inclined plane, it is advantageous to realize the total reflection of the light at the light outlet 33, complete the export of the light to the orthographic viewing angle, and form a good lighting effect.

As an optional embodiment, a thickness of the first refraction portion 35 is 1-2 μm.

The main function of the first refraction portion 35 is to optically cooperate with the second refraction layer 32, thereby increasing the brightness at the light outlet 33. However, the first refraction portion 35 will block the incoming light at the second area NA, therefore, in this embodiment, the thickness of the first refraction portion 35 is reduced and controlled at 1-2 μm, which is beneficial to the entry of external light. In the present application, the specific thickness of the first refraction portion 35 is not specifically limited.

The embodiment of the present application provides a display panel 100, by controlling the thickness of the first refraction portion 35, on the basis that the requirement of improving the display brightness is met, it is beneficial to reduce the blocking of incoming light in the second area NA, and it is convenient to realize the improvement of the light transmittance of the second area NA.

As an optional embodiment, referring to FIGS. 11 and 12, the display panel 100 includes an encapsulation layer 40 and a touch layer 50, the encapsulation layer 40 is arranged on a side of the light-emitting layer 20 away from the substrate 10, the touch layer 50 is arranged on a side of the encapsulation layer 40 away from the light-emitting layer 20, and the light processing layer 30 is arranged between the encapsulation layer 40 and the touch layer 50.

The overall setting position of the light processing layer 30 can also affect the light transmittance of the second area NA of the display panel 100. The encapsulation layer 40 is arranged on the light-emitting layer 20 to isolate and protect the light-emitting unit 21, which can effectively isolate the external water and oxygen environment with the light-emitting unit 21, and prevent adverse effects on the normal display of the light-emitting unit 21. Optionally, the encapsulation layer 40 can adopt a combination of organic encapsulation material and inorganic encapsulation material.

Optionally, the light processing layer 30 can usually be arranged on the top surface, that is, on the touch layer 50, so as to adjust the light output of the display panel 100. In this embodiment, the light processing layer 30 can be arranged between the encapsulation layer 40 and the touch layer 50 to make the setting position of the light processing layer 30 lower, it is beneficial to the entry of external light on the basis of ensuring that the display brightness is improved by using the light processing layer 30, thereby further improving the light transmittance of the second area NA. In the present application, there is no special restriction on the specific setting position of the light processing layer 30, as long as it is ensured that the luminous brightness and light transmittance of the second area NA can be improved at the same time.

The embodiment of the present application provides a display panel 100, wherein the light processing layer 30 is arranged between the encapsulation layer 40 and the touch layer 50, on the basis of the display brightness being improved using the light processing layer 30, the light transmittance can be increased by adjusting the occupied area of the first refraction portion 35 in the second area NA, the overall position of the light processing layer 30 can be adjusted to further improve the light transmittance, thereby a better imaging effect can be achieved.

A display apparatus is provided according to the embodiment of the present application, which includes the display panel 100 as described above.

The embodiments of the present application provides a display panel and a display apparatus, wherein a light processing layer is arranged on the light-emitting layer, a first refraction layer and a second refraction layer with different refractive indexes are arranged in the light processing layer, and a light outlet corresponding to a corresponding light-emitting unit is arranged on the first refraction layer. Due to the light total reflection formed by the refractive index difference between the first refraction layer and the second refraction layer, more light is output from the orthographic viewing angle of the light outlet, the display brightness of the first area and the second area of the display panel can be thus improved. On this basis, the area ratio of the first refraction layer to the second refraction layer in the first area and the second area can be adjusted, and by making the area proportion of the first refraction layer in the second area smaller than that in the first area, the influence of the light processing layer on the light input in the second area is reduced, so that the light input in the second area is larger than that in the first area. Therefore on the basis of improving the display brightness of the second area by using the light processing layer, the light input in the second area can be increased, and finally the imaging effect can be improved and the influence of the light processing layer on the imaging can be reduced.

Although the present application has been described with reference to preferred embodiments, without departing from the scope of the present application, various improvements can be made and components in the embodiments can be replaced with equivalents. Particularly, the technical features mentioned in the various embodiments can be combined in any way as long as there is no structural conflict. The present application is not limited to the specific embodiments disclosed herein, but includes all technical solutions that fall within the scope of the claims.

What is claimed is:

1. A display panel comprising a first area and a second area, a light transmittance of the second area being greater than that of the first area, wherein the display panel comprising:
a substrate;
a light-emitting layer arranged on the substrate, wherein the light-emitting layer comprises a plurality of light-emitting units arranged at intervals;
a light processing layer arranged on a side of the light-emitting layer away from the substrate, the light processing layer comprising a first refraction layer and a second refraction layer that covers the first refraction layer, wherein the first refraction layer is provided with a light outlet overlapped with the light-emitting unit in a thickness direction of the substrate, and the refractive index of the second refraction layer is greater than that of the first refraction layer,
wherein in the direction of the thickness, a ratio of an orthographic projection area of the first refraction layer to an orthographic projection area of the second refraction layer on the second area is less than a ratio of an orthographic projection area of the first refraction layer to an orthographic projection area of the second refraction layer on the first area.

2. The display panel of claim 1, wherein the light-emitting layer comprises a pixel limiting portion, the pixel limiting portion encloses a pixel opening, the light-emitting unit is arranged in the pixel opening, and wherein in the second area, the first refraction layer is provided with a light inlet, and a part of the second refraction layer is filled in the light inlet and the light outlet, an orthographic projection of the light inlet in the thickness direction is located on the pixel limiting portion, and the light outlet is arranged in the thickness direction corresponding to the pixel opening.

3. The display panel of claim 2, wherein the first refraction layer comprises a first refraction portion, and in the second area, an orthographic projection of the first refraction portion in the thickness direction is located on the pixel limiting portion, the first refraction portion encloses the light outlet and the light inlet which are arranged alternately.

4. The display panel of claim 3, wherein the light-emitting unit comprises a plurality of sub-pixels arranged at intervals, the orthographic projection of the first refraction portion in the thickness direction continuously surrounds at least two adjacent sub-pixels, the sub-pixel is arranged corresponding to the light outlet in the thickness direction, the pixel limiting portion between the adjacent sub-pixels is arranged corresponding to the light inlet in the thickness direction, and at least a part of the light outlet and the light inlet are arranged at an interval.

5. The display panel of claim 4, wherein the light-emitting unit comprises a first sub-pixel, a second sub-pixel and a third sub-pixel arranged at intervals, the orthographic projection of the first refractive portion in the thickness direction continuously surrounds the first sub-pixel and the second sub-pixel of the first light-emitting unit, the third sub-pixel of the first light-emitting unit and the first sub-pixel of an adjacent second light-emitting unit, and the second sub-pixel and the third sub-pixel of the second light-emitting unit.

6. The display panel of claim 4, wherein the light-emitting unit comprises a first sub-pixel, a second sub-pixel and a third sub-pixel arranged at intervals, the orthographic projection of the first refractive portion in the thickness direction surrounds the first sub-pixel, the second sub-pixel and the third sub-pixel at the same time.

7. The display panel of claim 4, wherein the orthographic projection of the first refraction portion in the thickness direction is arranged around an edge of the second area, and the light outlet and the light inlet enclosed by the first refraction portion are all continuous with each other.

8. The display panel of claim 3, wherein the light-emitting unit comprises a plurality of sub-pixels arranged at intervals, the orthographic projection of the first refraction portion in the thickness direction surrounds a corresponding sub-pixel, the sub-pixel is arranged corresponding to the light outlet in the thickness direction, and the first refraction portions corresponding to the adjacent sub-pixels are arranged at an interval to form the light inlet, the light outlet is spaced from the light inlet.

9. The display panel of claim 8, wherein the orthographic projection of the light outlet in the thickness direction at least covers the corresponding sub-pixel.

10. The display panel of claim 9, wherein a size of an orthographic projection of the light outlet in the thickness direction is larger than a size of the pixel opening and the distance between the light outlet and the sub-pixel is 0-2 μm.

11. The display panel of claim 3, wherein the light-emitting unit comprises a plurality of sub-pixels arranged at intervals, the second area comprises a first part and a second part, a resolution of the first part is greater than a resolution of the second part, the orthographic projection of the first refraction portion in the first part in the thickness direction is arranged around at least two adjacent sub-pixels at the same time, the orthographic projection of the first refraction portion in the second part in the thickness direction surrounds a corresponding sub-pixel.

12. The display panel of claim 11, wherein a number of sub-pixels surrounded by the first refraction portion is decreased in a direction from the first part to the second part.

13. The display panel of claim 3, wherein the first refraction portion comprises a light contact surface located on a side of the first refraction portion close to the light inlet, and the light contact surface is arranged as an inclined plane.

14. The display panel of claim 3, wherein a thickness of the first refraction portion is 1-2 μm.

15. The display panel of claim 1, wherein the display panel comprises an encapsulation layer and a touch layer, the encapsulation layer is arranged on a side of the light-emitting layer away from the substrate, the touch layer is arranged on a side of the encapsulation layer away from the light-emitting layer, and the light processing layer is arranged between the encapsulation layer and the touch layer.

16. A display apparatus comprising the display panel of claim 1.
